(19) United States
(12) Patent Application Publication
(10) Pub. No.: US 2010/0258157 A1
(43) Pub. Date: Oct. 14, 2010

(54) WATERTIGHT CONNECTOR AND PHOTOVOLTAIC POWER GENERATING APPARATUS

(75) Inventor: Atsushi Arai, Toyama (JP)

Correspondence Address: DARBY & DARBY P.C., P.O. BOX 770, Church Street Station, New York, NY, 10008-0770, US

(73) Assignee: SMK CORPORATION, Tokyo (JP)

(21) Appl. No.: 12/715,791

(22) Filed: Mar. 2, 2010

(30) Foreign Application Priority Data
Apr. 13, 2009 (JP) 2009-96636

(51) Int. Cl. H01L 31/042; H01R 13/52

(52) U.S. Cl. 136/244; 439/278

(57) ABSTRACT

A watertight connection includes a male side and female side pair of terminal fittings. Each of the terminal fittings is mounted to an end part of an electrical line. Plug housings having male side and female side terminal fittings of two poles are correspondingly mounted, male side-to-male side and female side-to-female side. Insulation members each house a rear end part of a plug housing and an end part of an electrical lines. A sealing material member prevents moisture from penetrating into the insulation member. Openings, which expose the front end part of each plug housing outside of the insulation member, are formed in an inner wall surface of the insulation member. An outer circumferential surface of the rear end part of each of the plug housings is brought into close contact with the sealing material member to couple the plug housings and the insulation member in a watertight state.

### CROSS REFERENCE TO PRIOR APPLICATIONS

The present application claims priority under U.S.C. §119 to Japanese Patent Application No. 2009-96636, filed Apr. 13, 2009. The content of the application is incorporated herein by reference in its entirety.

1. Field of the Invention

The present invention relates to a watertight connector, and is particular to a watertight connector for a photovoltaic power generating apparatus.

2. Background of the Invention

In a photovoltaic power generating apparatus comprising solar panels, each of which is composed of a plurality of photovoltaic cells, connecting the outputs of the solar panels in series or in parallel allows for the collection of the electric power output from the solar panels. This output is then supplied to, for example, a later stage inverter and output as AC electrical power. Because associated electrical wiring is often installed outdoors, there is a demand for increasing the reliability of a watertight structure of the apparatus that prevents water from penetrating electrically conductive portions of the electrical wiring, particularly at connection locations.

One example of a connector that is used to connect this type of electrical wiring is a single pole watertight connector disclosed in Japanese Unexamined Patent Application Publication No. 2008-130462 (“the '462 Publication”) which is hereby incorporated by reference herein in its entirety. This connector is used for single core electrical wiring and includes: a housing, wherein a terminal fitting connected to a tip of a cable is inserted; a watertight tube, which is mounted around the outer circumference of the housing; and a clamping cover, which is capable of splitting in half and clamping the watertight tube from the outer circumferential side.

Using such a watertight connector makes it possible to configure, for example, a photovoltaic power generating apparatus 10 as shown in FIG. 13. The photovoltaic power generating apparatus 10 is installed on, for example, the roof of a house or the rooftop of a building; furthermore, nine solar panels 12a1-12a3, 12b1-12b3, 12c1-12c3 receive sunlight, and the electric power generated by each of the solar panels is output from both a positive side output terminal 14a and a negative side output terminal 14b inside an output terminal box 14 that is provided to the rear surface of each of the panels 12a1-12a3, 12b1-12b3, 12c1-12c3 and includes built-in devices such as diodes. Output cable pairs 16, 18, each of which comprises a pair of single core cables (i.e., a positive side and a negative side), are connected on the left and right to the output terminals 14a, 14b of each of the output terminal boxes 14. A single pole female side plug 20 is mounted to the positive side end part of each of the output cable pairs 16, and a single pole male side plug 22 is mounted to the negative side end part of each of the output cable pairs 16; furthermore, one of the male side plugs 22 is mounted to the positive side end part of each of the output cable pairs 18, and one of the female side plugs 20 is mounted to the negative side end part of each of the output cable pairs 18. Furthermore, a watertight connector or the like, as disclosed in The '462 Publication, is used for each of the female side plugs 20 and the male side plugs 22.

The output cable pair 16 of the solar panel 12a2 is connected to the output cable pair 18 of the solar panel 12a3, and the output cable pair 18 of the solar panel 12a2 is connected to the output cable pair 16 of the solar panel 12a1. At this time, connecting corresponding output cable pairs to one another by mating the female side plugs 20 and the male side plugs 22 on the end parts together in a watertight state and connecting the outputs of the three solar panels 12a1-12a3 in parallel configures a solar panel group 12a. Solar panel groups 12b, 12c are similarly configured by likewise connecting the outputs of the three solar panels 12b1-12b3 and the three solar panels 12c1-12c3 in parallel.

Furthermore, the negative side of the output cable pair 16 of the solar panel 12a3 and the positive side of the output cable pair 16 of the solar panel 12b3 are connected by a harness 24, wherein one of the female side plugs 20 and one of the male side plugs 22 are mounted to the ends of a cable. In addition, the negative side of the output cable pair 16 of the solar panel 12b3 and the positive side of the output cable pair 16 of the solar panel 12c3 are connected by a harness 26, which is configured similarly to the harness 24. Furthermore, one end of a harness 28, which is configured similarly to the harness 24, is connected to the positive side of the output cable pair 16 of the solar panel 12a3, and one end of a harness 30, which is configured similarly to the harness 24, is likewise connected to the negative side of the output cable pair 16 of the solar panel 12c3. At this time, the corresponding output cable pairs 16 and the harnesses 24, 26 are connected by mating the female side plugs 20 and the male side plugs 22 of the end parts in a watertight state. Furthermore, the outputs of the solar panels 12a1-12a3, the solar panels 12b1-12b3, and the solar panels 12c1-12c3 are connected in series, and the other ends of the harnesses 28, 30 are connected to a later stage inverter and the like (not shown), and the power supplied from the solar panels 12a1-12a3, 12b1-12b3, 12c1-12c3 is converted to AC electrical power and then output.

Japanese Unexamined Patent Application Publication No. 2002-9326 (“the '326 Publication”), which is hereby incorporated by reference herein in its entirety, discloses a double pole watertight connector that is used in a photovoltaic power generating apparatus and comprises: a male type connector housing, which is provided with a pair of parallel tubular protruding parts wherein a female type terminal is installed in each of the tubular protruding parts; and a female type connector housing, which is provided with a pair of parallel mating holes wherein the tubular protruding parts (wherein the female type terminals are installed) are inserted. The external shapes of these tubular protruding parts are different from one another, and the inner shapes of the mating holes are correspondingly different from one another. The male type and female type connector housings are formed by molding insert members, wherein a hard synthetic resin is selectively used in the male type connector housing and a soft synthetic resin is selectively used in the female type connector housing.

Nevertheless, when configuring, for example, the photovoltaic power generating apparatus 10 in the case of the single pole watertight connector recited in the “462 Publication, the procedure for mounting each of the female side plugs 20 and the male side plugs 22 to the positive and negative sides of the end parts of the output cable pairs 16, 18 is extremely complicated, and it is also easy to confuse the polarities, which is a problem. In addition, when configuring the connector housings by molding insert members for, for example, the double pole watertight connector in the '326 Publication, the manufacturing process is complicated. Furthermore, once a plug is mounted to an end part of a cable, it cannot be removed. Accordingly, it is difficult to, for example, remove and change the polarity of the connector at a later time or to adjust the length of the cable, and therefore this connector is not easy to use at an installation worksite. In addition, it is problematic to apply excess cable from, for example, a worksite or a manufacturing plant to another purpose, such as connecting the components of the abovementioned connector housing to some other electrical wiring, and therefore this connector has poor general versatility as a connector component for wiring.

Moreover, because the electrical power generating efficiency of solar panels used in photovoltaic power generation in recent years has improved and the size of solar panels has increased, both the electrical power output by such solar panels and the voltages impressed on terminals have increased. Accordingly, there is an increased demand for connecting a greater number of solar panels in parallel to extract more electrical power.

### SUMMARY OF THE INVENTION

The present invention is directed to a watertight connector for a photovoltaic power generating apparatus that can be easily and reliably assembled, that is highly versatile as a connector component for wiring, and that possesses excellent watertightness performance.

A watertight connector according to one embodiment of the present invention comprises: a male side plug and a female side plug, each of which comprises: a male side or female side pair of terminal fittings, wherein a mating portion that mates with its counterpart side terminal fitting is provided to each of the tips, and wherein each of the terminal fittings is mounted to an end part of an electrical line; a male side or female side plug housing, wherein each of the plug housings comprises the terminal fittings of two poles (i.e., positive and negative) that are correspondingly mounted, male side-to-male side or female side-to-female side, to the male side or female side pair of terminal fittings wherein the mating part that mates with its counterpart side is provided to the tip of each of the terminal fittings; an insulation member, which houses at least a rear end part of the plug housing and the end parts of the electrical lines; and a watertight member, which prevents moisture from penetrating into the insulation member; wherein the watertight member is a tubular sealing material member that is mounted such that it spans the outer circumferences of the electrical wiring lines and the plug housing; in an inner wall surface, which is formed in a hollow of the insulation member, the rear end part of the plug housing, which holds the pair of terminal fittings, is housed and openings that expose a front end part of the plug housing to the outside of the insulation member are formed; and the inner wall surface of the insulation member and the outer circumferential surfaces of the electrical wiring lines and the rear end part of the plug housing are brought into close contact with the sealing material member, and thereby the plug housing and the insulation member are coupled in a watertight state.

The insulation member is capable of dual use and therefore can be mounted to both the male side plug housing and the female side plug housing; and each of the mating parts of the male side and female side plug housings have a shape that is capable of mating with and connecting to only the terminal fitting of the corresponding polarity.

Furthermore, the insulation member is an insulation casing, which is provided with a support wall that has a tip edge that makes contact with the outer circumferential surface of the sealing material member at the inner wall surface in the vicinity of the openings, and the outer circumferential surfaces of the support wall and the rear end part of the plug housing make close contact with the sealing material, thereby coupling the plug housing and the insulation casing in a watertight state.

In addition, the outer circumferential surface of the male side plug housing and the outer circumferential surface of the female side plug housing each pinch the same type of sealing material member against the support wall, thereby coupling the corresponding plug housing and the corresponding insulation casing in the watertight state.

Furthermore, the sealing material member is preferably capable of dual use and therefore can be mounted to both the terminal fittings and the plug housing on the male side and the terminal fittings and the plug housing on the female side. In addition, the present invention is also directed to a photovoltaic power generating apparatus that has a plurality of solar panels, each solar panel comprising photovoltaic cells, wherein output terminals that comprise a pair of two poles (i.e., positive and negative) for each of the solar panels are connected via a watertight connector and a cable. The electric power generated by the plurality of solar panels is output collectively. The watertight connector comprises a male side plug and a female side plug, each of which comprises: a male side or female side pair of terminal fittings, wherein a mating portion that mates with its counterpart side is provided to each of the tips, and wherein each of the terminal fittings is mounted to an end part of an electrical line; a male side or female side plug housing, wherein each of the plug housings comprises the terminal fittings of two poles (i.e., positive and negative) that are correspondingly mounted, male side-to-male side or female side-to-female side, to the male side or female side pair of terminal fittings wherein the mating part that mates with its counterpart side is provided to the tip of each of the terminal fittings; an insulation member, which houses at least a rear end part of the plug housing and the end parts of the electrical lines; and a watertight member, which prevents moisture from penetrating into the insulation member; wherein the watertight member is a tubular sealing material member that is mounted such that it spans the outer circumferences of the electrical wiring lines and the plug housing.

A rear end part of the plug housing, which holds the pair of terminal fittings, is housed in an inner wall surface, which is formed in a hollow of the insulation member, and openings, which externally expose the insulation member, are formed in a front end part of the plug housing; and the inner wall surface of the insulation member and the outer circumferential surfaces of the electrical wiring lines and the rear end part of the plug housing are brought into close contact with the sealing material member, and thereby the plug housing and the insulation member are coupled in a watertight state. In each of the solar panels, the male side plug of the two poles (i.e., positive and negative) connected via the cable is connected to one of the output terminals, the female side plug of the two poles (i.e., positive and negative) connected via the cables is likewise connected to the other output terminal, and thereby adjacent solar panels can be similarly connected to one another by the male side plug on one side and the female side plug on the other side. In addition, in each of the solar panels, output terminals of the same polarity are connected to one another via the cable and via the male side plug and the female side plug, which are mated to one another, and the solar panels are electrically connected in parallel.

Furthermore, the present invention is directed to a photovoltaic power generating apparatus that comprises a plurality of solar panel groups, each of which is formed by connecting a plurality of the solar panels in parallel, and is formed by connecting each of the solar panel groups with a harness, wherein a male side or a female side plug is provided in the same way to the terminal of each of the solar panel groups. A female side or male side plug, which mates with a corresponding male side or female side plug, is provided in the same number as the solar panel groups to the harness; and the harness connects each of the solar panel groups in series.

The watertight connector of the present invention has general versatility in that it can be used by selectively combining multiple types of components when mounting the male side and female side plugs to the end parts of electrical wiring lines, such as cables. In addition, with the present invention, it is possible to use, for example, spare parts or the components remaining from the disassembly of a previously mounted male side and female side plug for some other purpose, such as in another plug; therefore, the present invention exhibits excellent economy and is convenient to use in wiring work. In addition, because the two poles (i.e., positive and negative) of the female side and the male side plug housings are integrated and have shapes such that their mating parts can mate with one another only in polarities of one direction, mismounting and miswiring tend not to occur during wiring work.

In addition, a sealed structure that pinches the sealing material member, which ensures watertightness, is more reliably obtained by pinching one location of at least one sealing material member using a combination of any of the electrical wiring line, the insulation casing, and the plug housing. Furthermore, if each sealing material member is pinched in multiple locations, then watertightness performance can easily be further improved.

The photovoltaic power generating apparatus according to the present invention uses the abovementioned watertight connector, which makes it possible to perform assembly easily and accurately. Furthermore, because numerous solar panels are connected in parallel, the present invention can also be adapted to large capacity photovoltaic power generating apparatuses.

### BRIEF DESCRIPTION OF THE DRAWINGS

The foregoing and other features of the present invention will be more readily apparent from the following detailed description and drawings of illustrative embodiments of the invention in which:

FIG. 1(a) is a plan view that shows a male side plug according to an embodiment of the present invention;

FIG. 1(b) is a plan view that shows a female side plug according to the embodiment of FIG. 1(a);

FIG. 2(a) is a front view that shows the male side plug according to the embodiment of FIG. 1(a);

FIG. 2(b) is a front view that shows the female side plug according to the embodiment of FIG. 1(a).

FIG. 3(a) is a transverse cross sectional view of the male side plug of FIG. 1(a)

FIG. 3(b) is a transverse cross sectional view of the female side plug of FIG. 1(b).

FIG. 4(a) is a longitudinal cross sectional view of the male side plug of FIG. 1(a),

FIG. 4(b) is a longitudinal cross sectional view of the female side plug of FIG. 1(b).

FIG. 5 is a plan view that shows a connected state of the male side plug and the female side plug of FIGS. 1(a) and 1(b).

FIG. 6 is a front view of the connected state of the male side plug and the female side plug of FIG. 5.

FIG. 7 is a transverse cross sectional view of the connected state of the male side plug and the female side plug of FIG. 5.

FIG. 8 is a longitudinal cross sectional view of the connected state of the male side plug and the female side plug of FIG. 5.

FIG. 9(a) is a plan view that shows a female cap according to the embodiment of FIGS. 1(a) and 1(b).

FIG. 9(b) is a front view of the male Cap of FIG. 9(a),

FIG. 9(c) is a transverse cross sectional view of the female cap of FIG. 9(a),

FIG. 9(d) is a longitudinal cross sectional view of the female cap of FIG. 9(a).

FIG. 10 is a schematic drawing that shows an example of electrical wiring of a photovoltaic power generating apparatus with watertight connectors according to the embodiment of FIGS. 1(a) and 1(b).

FIG. 11(a) is an enlarged transverse cross sectional view that shows a male side plug according to another embodiment of the present invention.

FIG. 11(b) is a transverse cross sectional view that shows a female side plug for the embodiment of FIG. 11(a).

FIG. 12(a) is a longitudinal cross sectional view that shows the male side plug according to the embodiment of FIG. 11(a),

FIG. 12(b) is a longitudinal cross sectional view that shows the female side plug of the embodiment of FIG. 11(b).

FIG. 13 is a schematic drawing that shows one example of electrical wiring of the photovoltaic power generating apparatus wherein conventional watertight connectors are used.

Like reference numerals are used in the drawing figures to connote like elements of the invention.

### EXPLANATION OF SYMBOLS

10, 40 Photovoltaic power generating apparatuses
12a, 12b, 12c Solar panel groups
16, 18 Output cable pairs
42, 102 Male side plugs
44, 104 Female side plugs
46 Harness
46a, 46b, 46c, 46d Single core cables
51 Female cap
52, 114 Upper covers
54, 116 Lower covers
56, 108 Insulation casings
56c, 108c Inner wall surfaces
58 Single core cable
60 Male side plug housing
62a, 62b, 70a, 70b Mating parts
66 Female side plug housing
74a, 74b O-rings
76 Male side terminal fitting
78 Female side terminal fitting
80 Rear end protruding part
84, 110 Sealing material members
86 Large diameter part
88a, 88b, 112 Small diameter parts
92, 94 Support walls
92a, 92b Support surfaces
94a Support surface
106 Dual core cable

### DETAILED DESCRIPTION OF THE INVENTION

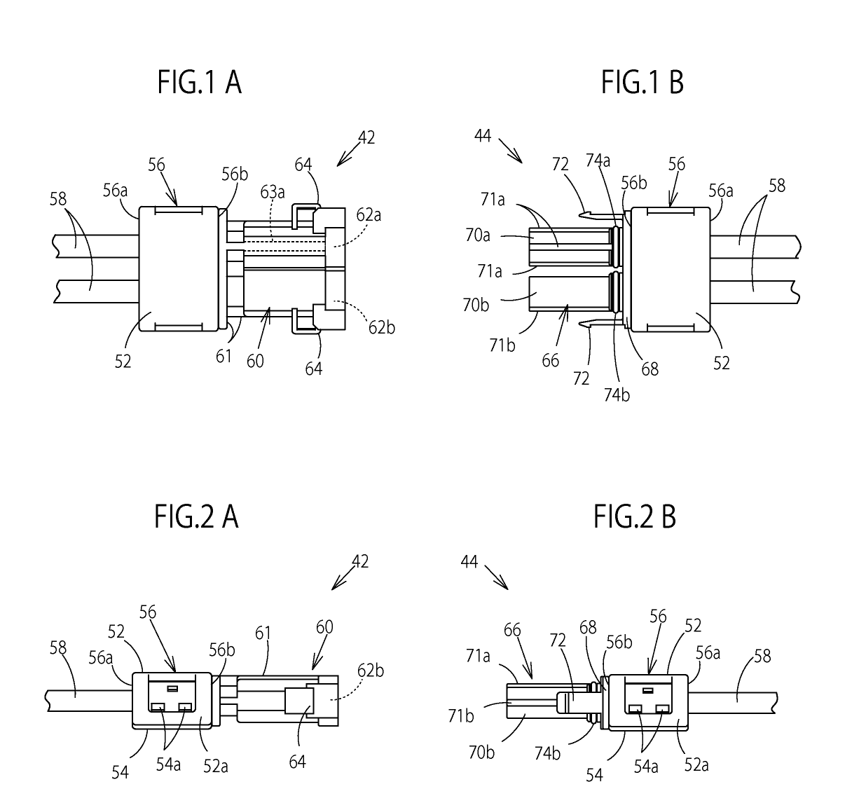

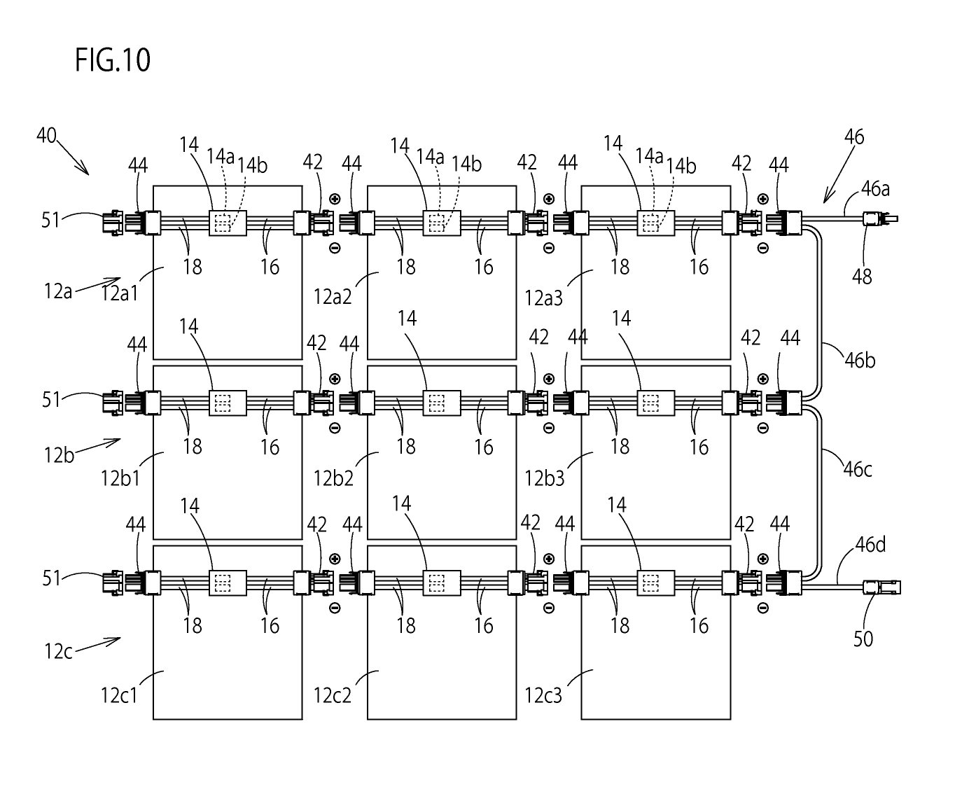

A first embodiment of a watertight connector according to the present invention will now be explained, referencing FIG. 1 through FIG. 10. As shown in FIG. 10, male side plugs 42 and female side plugs 44, which constitute the watertight connectors of the present embodiment, are used in the electrical wiring of a photovoltaic power generating apparatus 40 that is installed on, for example, a roof of a house or the rooftop of a building. In the explanation below, constituent elements of the photovoltaic power generating apparatus 40 that are the same as those in the conventional photovoltaic power generating apparatus 10 are assigned the same symbols.

The photovoltaic power generating apparatus 40 receives sunlight via nine solar panels 12a1-12a3, 12b1-12b3, 12c1-12c3, each of which is composed of photovoltaic cells, and outputs electric power generated by each of the solar panels 12a1-12a3, 12b1-12b3, 12c1-12c3 from a positive side output terminal 14a and a negative side output terminal 14b inside an output terminal box 14, one of which is provided to the rear surface of each of the panels 12a1-12a3, 12b1-12b3, 12c1-12c3 and includes built-in devices such as diodes. Output cable pairs 16, 18, each of which comprises a pair of single core cables (i.e., a positive side and a negative side), are connected on the left and right to the output terminals 14a, 14b of each of the output terminal boxes 14. A double pole male side plug 42, in which the positive side and the negative side are integrated, is mounted to the end part of each of the output cable pairs 16, and a double pole female side plug 44, in which the positive side and the negative side are integrated, is likewise mounted to the end part of each of the output cable pairs 18.

The output cable pair 16 of the solar panel 12a2 is connected to the output cable pair 18 of the solar panel 12a3, and the output cable pair 18 of the solar panel 12a2 is connected to the output cable pair 16 of the solar panel 12a1. Connecting corresponding output cable pairs to one another by mating the male side plugs 42 and the female side plugs 44 of the end parts in a watertight state and connecting outputs of the same polarity of the three solar panels 12a1-12a3 in parallel configures the solar panel group 12a. The solar panel groups 12b, 12c are similarly configured by connecting the outputs of the three solar panels 12b1-12b3 and the three solar panels 12c1-12c3 in parallel.

In addition, a harness 46, which comprises three of the female side plugs 44, is connected to the output cable pairs 16 of the solar panels 12a3, 12b3, 12c3. Of the female side plugs 44 of the harness 46, the female side plug 44 that is connected to the output cable pair 16 of the solar panel 12a3 has one end of a single core cable 46a mounted to its positive side and one end of a single core cable 46b mounted to its negative side. A positive side plug 48 is mounted to the other end of the single core cable 46a.

In addition, of the female side plugs 44 of the harness 46, the female side plug 44 that is connected to the output cable pair 16 of the solar panel 12b3 has the other end of the single core cable 46b mounted to its positive side and one end of a single core cable 46c mounted to its negative side.

Furthermore, of the female side plugs 44 of the harness 46, the female side plug 44 that is connected to the output cable pair 16 of the solar panel 12c3 has the other end of the single core cable 46c mounted to its positive side and one end of a single core cable 46d mounted to its negative side. A negative side plug 50 is mounted to the other end of the single core cable 46d.

Thereby, the single core cables 46a-46d and the corresponding output cable pairs 16 are connected by the mating of the female side plugs 44 and the male side plugs 42 of the end parts in the watertight state, and the outputs of the solar panels 12a1-12a3, the solar panels 12b1-12b3, and the solar panels 12c1-12c3 are connected in series. Furthermore, the other ends of the single core cables 46a, 46d are connected to, for example, a later stage inverter (not shown) via the positive side plug 48 and the negative side plug 50, and the electrical power supplied from each of the solar panels 12a1-12a3, 12b1-12b3, 12c1-12c3 is converted to AC electrical power and output.

In addition, a female cap 51 is mounted to each of the female side plugs 44 mounted to the end parts of the output cable pairs 18 of the solar panels 12a1, 12b1, 12c1, and thereby electrically conductive portions cover those female side plugs 44.

Next, the male side plug 42 and the female side plug 44 will be explained, referencing the drawings. As shown in FIG. 1(a) and FIG. 2(a), the male side plug 42 comprises an insulation casing 56, which is divided into an upper cover 52 and a lower cover 54, the inner side housing parts of which vertically face one another to form a box shaped insulation member; and a male side plug housing 60, wherein a portion of a case body 61 protrudes outwardly from a front wall 56b on the side of the insulation casing 56 opposite that of a rear wall 56a wherefrom single core cables 58 of the insulation casing 56 protrude. The case body 61 of the male side plug housing 60 has a substantially oblong shape; furthermore, mating parts 62a, 62b, wherein mating parts 70a, 70b of a female side plug housing 66 (discussed below) are inserted for mating therewith, are open on the tip side of the case body 61; in addition, retainer mechanisms 64, wherein a pair of retainer pieces 72 of the female side plug housing 66 are inserted for mating therewith, are provided to both sidewalls of the case body 61. In addition, a pair of engagement receiving parts 52a are provided to sidewalls of the upper cover 52 such that, in the assembled state, they are downward facing and engage with a pair of projections 54a, which are formed in sidewalls of the lower cover 54, to integrally fix the two covers 52, 54 to one another.

Moreover, as shown in FIG. 1(b) and FIG. 2(b), the female side plug 44 comprises: the insulation casing 56, which is the same as that of the male side plug 42; and the female side plug housing 66, a prescribed portion of which protrudes outwardly from the front wall 56b on the side of the insulation casing 56 opposite that of the rear wall 56a, wherefrom the single core cables 58 of the insulation casing 56 protrude. The female side plug housing 66 comprises a substrate 68, which is substantially rectangular; furthermore, the mating parts 70a, 70b, which are inserted into and mate with the mating parts 62a, 62b of the male side plug housing 60 on the counterpart side, are provided to be up erectly to the center part of a surface on the side of the substrate 68 opposite that of where the insulation casing 56 is proximate. Furthermore, a pair of retainer pieces 72 are provided laterally to the sides of the mating parts 70a, 70b, and these retainer pieces 72 are inserted in and engage with the retainer mechanisms 64 of the male side plug housing 60.

The side surfaces of the mating part 70a have a different shape to those of the mating part 70b: four ribs 71a are formed in the insertion direction on the side surfaces of the mating part 70a, and one rib 71b is formed in the insertion direction on the side surface of the mating part 70b. Likewise, inner circumferential surfaces of the mating part 62a have a different shape to those of the mating part 62b: four groove parts 63a, which correspond to the ribs 71a of the mating part 70a, are formed in the mating part 62a, and one groove part 63b, which corresponds to the one rib 71b of the mating part 70b, is formed in the mating part 62b.

In addition, O-rings 74a, 74b, which are preferably made of rubber and have outer diameters slightly larger than the outer circumferential diameters of the mating parts 70a, 70b, are fitted onto the base portions of the mating parts 70a, 70b. When mated with the male side plug housing 42 on the counterpart side, the outer circumferences of the O-rings 74a, 74b make contact with the inner circumferential surfaces of the mating parts 62a, 62b, and thereby seal any gap therebetween.

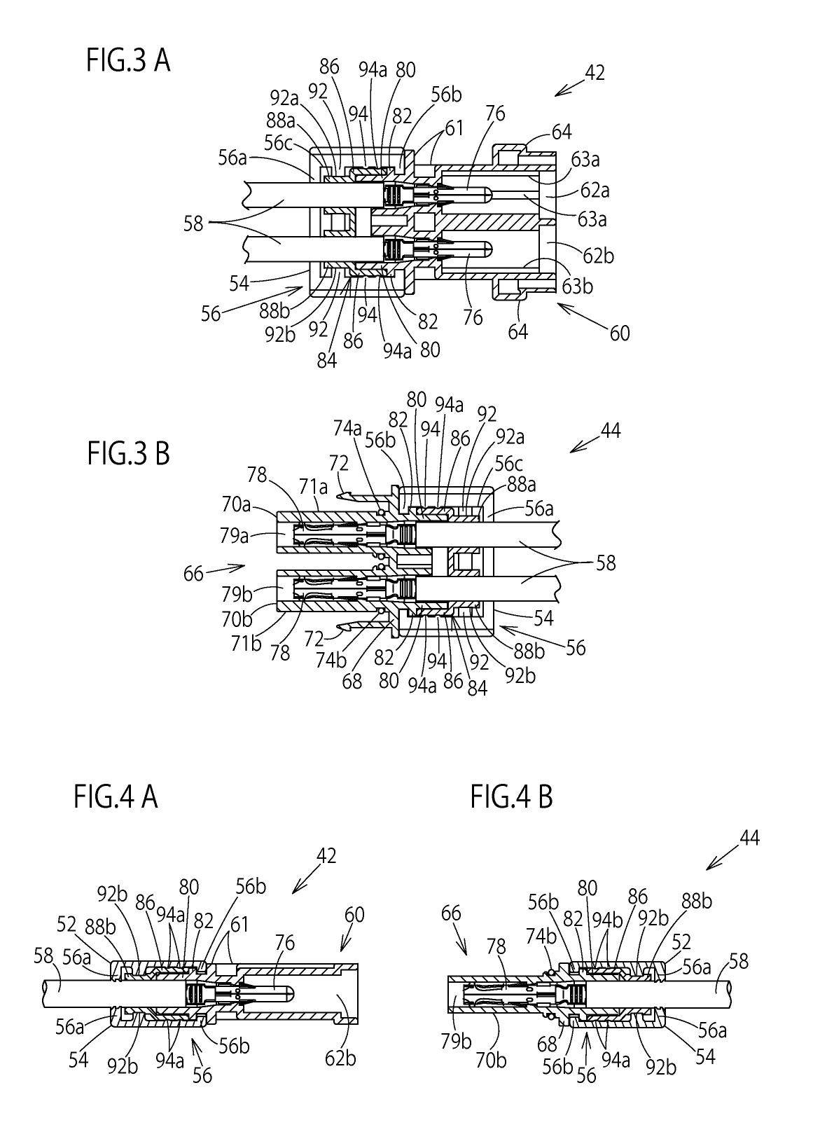

As shown in FIG. 3(a) and FIG. 4(a), two of the single core cables 58 and two of the male side terminal fittings 76, which are mounted to the end parts of the two single core cables 58, are housed inside the male side plug 42. First, the configuration of each constituent member of the male side plug 42 will be explained.

Each of the male side terminal fittings 76 is formed by, for example, bending a single forming piece punched from a thin metal plate of copper, copper alloy, or the like. On the tip side, an insertion part that meets with one of the female side terminal fittings 78 on the counterpart side (discussed below) is provided. The insertion part is formed by rolling the forming piece into a cylinder. In addition, the end part of the insertion part is sealed with a somewhat semispherical shape. Further, the cylindrical portion of the insertion part is provided with multiple latching pieces, which are formed by cutting and bending parts of the wall surface such that they face diagonally rearward directions. Moreover, a prescribed connecting part is provided on the base end side of each of the male side terminal fittings 78. In addition, each of the connecting parts and the core wire of the corresponding single core cable 58 are solidly connected by, for example, crimping.

The male side plug housing 60 is provided with a rear end protruding part 80, which is provided erectly to the rear end of the male side plug housing 60, namely, the cables 58 of the case body 61; furthermore, the inner side of the rear end protruding part 80 passes through the mating parts 62a, 62b continuously, and the outer side of the rear end protruding part 80 has an elliptical cylindrical shape. In addition, flange parts 82 are formed in the vicinity of the base of the rear end protruding part 80, and the flange parts 82 engage with the front wall 56b in the gaps between the case body 61 and the flange parts 82 when the rear end protruding part 80 is housed inside the insulation casing 56.

In addition, a sealing material member 84, which is a watertight member, is fitted to the rear end protruding part 80 of the male side plug housing 60. The sealing material member 84 is molded from a raw material that is capable of expanding and contracting, such as silicone rubber, and comprises: a large diameter part 86, which has a comparatively large elliptical cylindrical shape; and small diameter parts 88a, 88b, each of which has a cylindrical shape with a comparatively smaller outer diameter and is formed continuously with the large diameter part 86. Viewed from the ring shaped end surfaces of the small diameter parts 88a, 88b toward the large diameter part 86, the external shapes of the small diameter parts 88a, 88b fit within the elliptically shaped outer circumference of the large diameter part 86; furthermore, the small diameter parts 88a, 88b and the corresponding mating parts 62a, 62b are respectively disposed coaxially. Furthermore, the large diameter part 86 is fitted to the rear end protruding part 80 from the outer circumferential side, and the small diameter parts 88a, 88b cover the outer circumferential surfaces of the single core cables 58. At this time, because the inner circumferential shape of the large diameter part 86 is set slightly smaller than the outer circumferential shape of the rear end protruding part 80, the former can be brought into close contact with the latter. Likewise, because the inner diameters of the small diameter parts 88a, 88b are set slightly smaller than the insulation coating outer circumferential diameters of the single core cables 58, the inner circumferential surfaces of the small diameter parts 88a, 88b can be brought into close contact with the insulation coating outer circumferential surfaces of the two single core cables 58.

The inner side shapes of the upper cover 52 and the lower cover 54 that constitute the insulation casing 56 are formed such that they are planarly symmetric in the assembled state. Two semicircular notches are provided to the rear wall 56a of each of the covers 52, 54, and, in the assembled state, these two notches form substantially circular openings.

In addition, an inner wall surface 56c, which is disposed slightly to the inner side of the rear wall 56a of each of the covers 52, 54, is provided with a small diameter part supporting wall 92 and two large diameter part supporting walls 94 such that they connect the space between laterally opposed sidewalls. The small diameter part supporting wall 92 is provided in parallel with two support surfaces 92a, 92b, the upper ends of which are recessed in a semicircle. The diameter of the small diameter part supporting wall 92 is set slightly smaller than the outer diameters of the small diameter parts 88a, 88b of the sealing material member 84 that cover the outer circumferential surfaces of the single core cables 58. In addition, the large diameter part supporting wall 94 is likewise provided with support surfaces 94a, the upper ends of which are recessed in a semi-ellipse. Further, the shapes of the support surfaces 94a are set slightly smaller than the outer circumferential shape of the large diameter part 86 of the sealing material member 84 that is fitted to the rear end protruding part 80 of the male side plug housing 60 from the outer circumferential side. In addition, in the assembled state of the covers 52, 54, the support surfaces 94a form substantially elliptical through holes, and the support surfaces 92a, 92b form two substantially circular through holes.

The front walls 56b of the covers 52, 54 are each provided with a semi-elliptical notch, which engages with the gap portions between the flange parts 82 and the case body 61 of the male side plug housing 60, which was discussed above, thereby forming a substantially elliptical opening in the assembled state.

Next, the method of assembling one of the male side plugs 42 will be explained. First, one of the male side terminal fittings 76 is mounted to the end part of each of the two single core cables 58. Next, the tips of the two male side terminal fittings 76 mounted to the single core cables 58 are inserted in the sealing material member 84 from the small diameter parts 88a, 88b sides. Furthermore, when the male side terminal fittings 76 reach prescribed locations inside the mating parts 62a, 62b, the latching pieces of the male side terminal fittings 76 strike the protruding portions inside the mating parts 62a, 62b and are thereby retained and fixed. At this time, the positive and negative poles of the single core cables 58 must be installed correctly inside the male side plug housing 60. Accordingly, because the positions of the positive and negative poles can be discerned by the positions and number of the groove parts 63a, 63b formed in the mating parts 62a, 62b of the male side plug housing 60, the positive and negative poles can be mounted accurately. Subsequently, the large diameter part 86 of the sealing material member 84 is fitted to the rear end protruding part 80 of the male side plug housing 60, and the pair of male side terminal fittings 76 is mounted to the male side plug housing 60.

Next, the covers 52, 54 are respectively mounted from above and below. The single core cables 58 are inserted through and guided to the exterior of the two openings formed by the notches in the rear walls 56a of the two covers 52, 54. In addition, the opening formed by the notches in the front walls 56b of the two covers 52, 54 latch to and support the gap portions between the case body 61 and the flange parts 82 of the rear end protruding part 80 of the male side plug housing 60. In addition, the through holes formed by the support surfaces 92a, 92b of the two covers 52, 54 support the outer circumferential surfaces of the small diameter parts 88a, 88b of the sealing material member 84. Furthermore, the through holes formed by the support surfaces 94a of the two covers 52, 54 support the outer circumferential surface of the large diameter part 86 of the sealing material member 84. Furthermore, by engaging and fixing the projections 54a and the engagement receiving parts 52a to one another, the upper cover 52 and a lower cover 54 integrally form the insulation casing 56.

The diameters of the support surfaces 92a, 92b of the insulation casing 56, the outer circumferential diameters of the single core cables 58, and the inner diameters and outer diameters of the small diameter parts 88a, 88b of the sealing material member 84 all have size relationships as discussed above; therefore, the small diameter part 88b of the sealing material member 84 made of a soft material is pinched in a state of close contact between the support surfaces 92a, 92b and the outer circumferential surface of the corresponding single core cable 58, thereby sealing the spaces on the outer and inner sides of the sealing material member 84. Similarly, the shapes of the support surfaces 94a, the outer circumferential shape of the rear end protruding part 80, and the inner side and outer side shapes of the large diameter part 86 of the sealing material member 84 all have size relationships as discussed above. Therefore, the large diameter part 86 of the sealing material member 84 is pinched in a state of close contact between the support surfaces 94a and the outer circumferential surface of the rear end protruding part 80, thereby sealing the spaces on the outer side and the inner side of the sealing material member 84 such that they are in the watertight state.

As shown in FIG. 3(b) and FIG. 4(b), two single core cables 58 and two female side terminal fittings 78, which are mounted to the end parts of the two single core cables 58, are housed inside the female side plug 44. First, the configuration of the constituent members of the female side plug 44 will be explained.

Each of the female side terminal fittings 78 is formed by, for example, bending a single forming piece punched out from a thin metal plate. On each tip side thereof, an insertion receiving part is provided that mates with the corresponding male side terminal fitting 76 on the counterpart side. The insertion receiving part is preferably formed by rolling a forming piece into a cylinder; in addition, the end part of the insertion receiving part is open. Further, multiple latching pieces, which are formed by cutting out parts of the wall surface in diagonally rearward directions, are provided to the cylindrical portion of the insertion receiving part. Moreover, the rear end side, namely, the cable side, of each of the female side terminal fittings 78 is provided with a prescribed connecting part. In addition, the connecting part and the core wire of the corresponding single core cable 58 are connected solidly, by, for example, crimping.

Cavities 79a, 79b, which respectively pass through the interiors of the mating parts 70a, 70b, are provided to the substrate 68 of the female side plug housing 66. In addition, the surface on the opposite side of the substrate 68 is provided with the rear end protruding part 80, which protrudes to the inner side of the insulation casing 56. The inner side of the rear end protruding part 80 passes through the mating parts 70a, 70b continuously, and the outer side has an elliptical cylindrical shape. In addition, the flange parts 82 are formed in the vicinity of the base of the rear end protruding part 80, and when the rear end protruding part 80 is housed inside the insulation casing 56, the front wall 56b engages with the gap between the substrate 68 and the flange parts 82. Further, the shapes of the flange parts 82 and the rear end protruding part 80 of the female side plug housing 66 are the same as those of the male side plug housing 60.

In addition, the sealing material member 84 discussed above is likewise mounted to the rear end protruding part 80 of the female side plug housing 66. The large diameter part 86 of the sealing material member 84 is fitted to the rear end protruding part 80 from the outer circumferential side, and the small diameter parts 88a, 88b cover the outer circumferential surfaces of the single core cables 58. Because the inner circumferential shape of the large diameter part 86 is set slightly smaller than the outer circumferential shape of the rear end protruding part 80, the former can be brought into close contact with the latter. Likewise, because the inner diameters of the small diameter parts 88a, 88b are set slightly smaller than each of the insulation coating outer circumferential diameters of the single core cables 58, the inner circumferential surfaces of the small diameter parts 88a, 88b can be brought into close contact with the insulation coating outer circumferential surfaces of the single core cables 58.

Next, the method of assembling one of the female side plugs 44 will be explained. First, as in the male side plug 42, one of the female side terminal fittings 78 is mounted to the end part of each of the two single core cables 58. Next, the tips of the two female side terminal fittings 78 mounted to the single core cables 58 are inserted in the sealing material member 84 from the small diameter parts 88a, 88b sides. Furthermore, when the female side terminal fittings 78 reach prescribed locations inside the cavities 79a, 79b, the latching pieces of the female side terminal fittings 78 strike the protruding portions inside the cavities 79a, 79b and are thereby retained and fixed. At this time, too, the positive and negative poles of the single core cables 58 must be installed correctly inside the female side plug housing 66. Accordingly, because the positions of the positive and negative poles can be discerned by the positions and number of the ribs 71a, 71b formed in the mating parts 70a, 70b of the female side plug housing 66, the positive and negative poles can be mounted accurately. Subsequently, the large diameter part 86 of the sealing material member 84 is fitted to the rear end protruding part 80 of the female side plug housing 66, and the pair of female side terminal fittings 78 is mounted to the female side plug housing 66.

Next, the covers 52, 54 are respectively mounted from above and below using the same procedure as in the male side plug 42. The single core cables 58 are inserted through and guided to the exterior of the two openings formed by the notches in the rear walls 56a of the two covers 52, 54. In addition, the opening formed by the notches in the front walls 56b of the two covers 52, 54 latch to and support the gap portions between the substrate 68 and the flange parts 82 of the rear end protruding part 80 of the female side plug housing 66. The through holes formed by the support surfaces 92a, 92b of the two covers 52, 54 support the outer circumferential surfaces of the small diameter parts 88a, 88b of the sealing material member 84. Furthermore, the through holes formed by the support surfaces 94a of the two covers 52, 54 support the outer circumferential surface of the large diameter part 86 of the sealing material member 84. Furthermore, by engaging and fixing the projections 54a and the engagement receiving parts 52a to one another, the upper cover 52 and a lower cover 54 integrally form the insulation casing 56.

In this configuration, the small diameter parts 88a, 88b of the sealing material member 84 are pinched in a state of close contact between the support surfaces 92a, 92b and the outer circumferential surface of the single core cables 58, thereby sealing the spaces on the outer and inner sides of the sealing material member 84. Simultaneously, the large diameter part 86 of the sealing material member 84 is pinched in a state of close contact between the support surfaces 94a and the outer circumferential surface of the rear end protruding part 80, thereby sealing the spaces on the outer side and the inner side of the sealing material member 84.

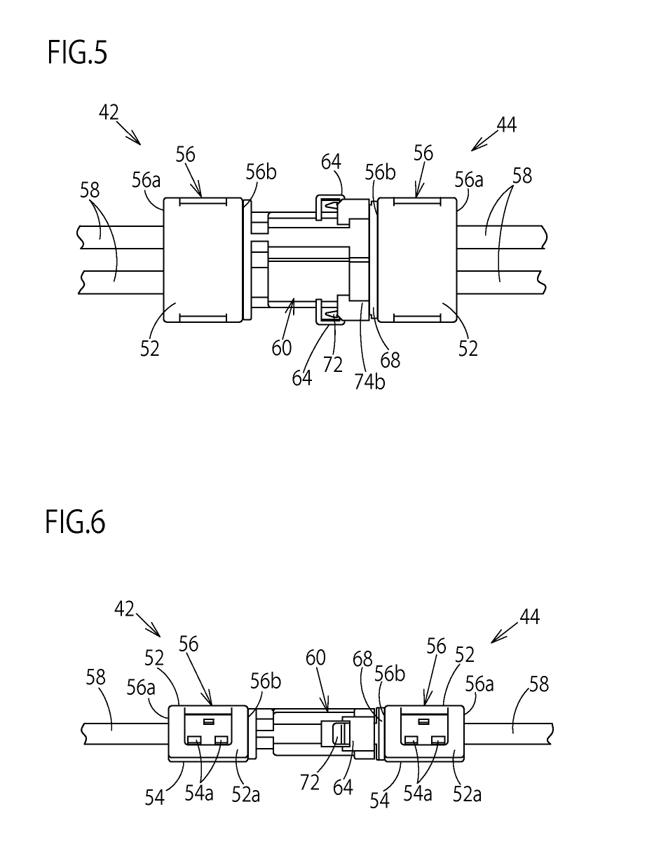

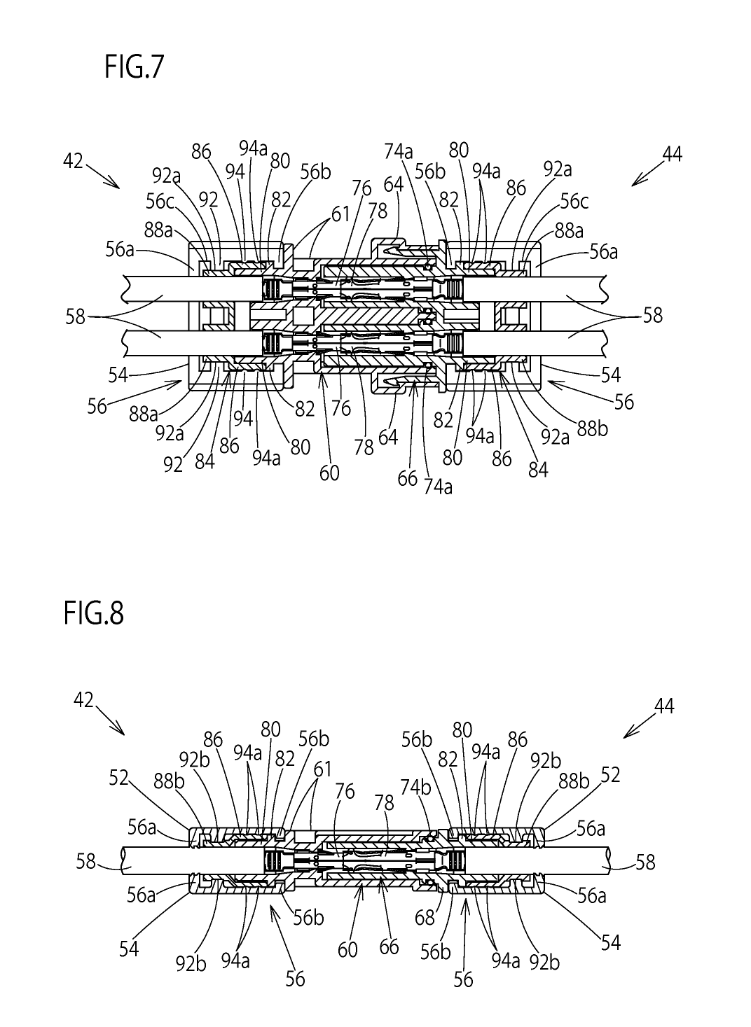

FIG. 5 through FIG. 8 show the state wherein the male side plug 42 and the female side plug 44 discussed above are connected together. As shown in FIG. 5 and FIG. 6, the structural connection and fixing is accomplished by respectively inserting the mating parts 70a, 70b of the female side plug housing 66 into the mating parts 62a, 62b of the male side plug housing 60 and engaging the retainer pieces 72 of the female side plug housing 66 with the retainer mechanisms 64 of the male side plug housing 60. In addition, as shown in FIG. 7 and FIG. 8, electrical continuity is achieved by inserting the tips of the male side terminal fittings 76 into the female side terminal fittings 78 from the tip openings, thereby mating them together. Furthermore, the space that extends from the openings at the rear wall 56a of the insulation casing 56 to the mating portions of the terminal fittings 76, 78 is sealed on the inner side and the outer side of the sealing material member 84 and thereby serves as a watertight structure that prevents the penetration of moisture. In addition, the space that extends from the gap between the inner side surfaces of the mating parts 62a, 62b of the male side plug housing 60 and the outer side surfaces of the mating parts 70a, 70b of the female side plug housing 66 to the mating portions of the terminal fittings 76, 78 is sealed by bringing the O-rings 74a, 74b at the bases of the mating parts 70a, 70b into close contact with the inner side surfaces of the mating parts 62a, 62b, which prevents the penetration of moisture.

The inner and outer constituent members of the male side plug 42 and the female side plug 44 that constitute the watertight connector of the present embodiment are preferably formed by the assembly process, which makes manufacturing easy. Moreover, the insulation casing 56 and the sealing material member 84 can be used both in the male side plug 42 and the female side plug 44; in addition, the male side plug 42 and the female side plug 44 can be easily detached even after they have been assembled, which facilitates materials control and also offers excellent economy through reuse.

In addition, as shown in FIG. 1 through FIG. 3, there is no risk that the male side plug 42 will be mistakenly fitted with the reverse polarity because the inner side shape of the mating part 62a and the inner side shape of the mating part 62b are different from one another, and the outer side shape of the mating part 70a of the female side plug 44 and the outer side shape of the mating part 70b of the female type plug 44 are correspondingly different from one another. Furthermore, even during the assembly of the single core cables 58, the positions of the positive and negative poles of the single core cables 58 can be differentiated easily and accurately based on the positions and number of the groove parts 63a, 63b, which are formed in both the male side plug housing 60 and the female type plug housing 66, and the ribs 71a, 71b, which are externally visible as shown in FIG. 1.

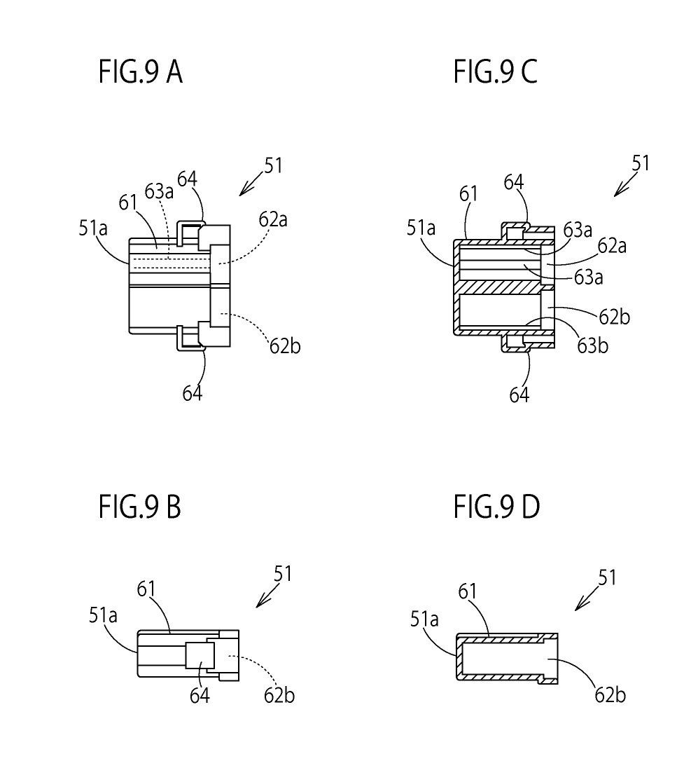

Furthermore, in the photovoltaic power generating apparatus 40, because the female side plugs 44 whereto the output cable pairs 18 of the solar panels 12a1, 12b1, 12c1 are mounted are electrically open, they are preferably covered with the female caps 51 in order to cover their exposed electrically conductive portions. As shown in FIGS. 9(a) through 9)d), given the configuration of the male side plug housing 60 as a starting point, each of the female caps 51 has a structure wherein the rear end protruding part 80 and the flange parts 82 are eliminated and a blocking wall 51a that blocks the two holes whereinto the male side terminal fittings 76 are inserted is further provided. Accordingly, the female cap 51 can be mounted to the female plug 44 using the same method as that used in the male side plug housing 60. In addition, the female cap 51 can seal the electrically conductive portions inside the female plug 44 by isolating the female plug 44 from the outside. If one of the male side plugs 42 were to be left electrically open for the sake of wiring design, then it, too, should be covered with a male cap (not shown) in order to cover its exposed electrically conductive portions. Given the configuration of the female side plug housing 66 as a starting point, each of the male caps should have a structure wherein the rear end protruding part 80 and the flange parts 82 are eliminated, and a blocking wall that blocks the two holes whereinto the male side terminal fittings 78 are inserted is further provided. Thereby, the male cap could be mounted to the male side plug 42 using the same method as that used in the female side plug housing 66. In addition, the male cap could seal the electrically conductive portions of the male side plug 42 by isolating the male side plug 42 from the outside.

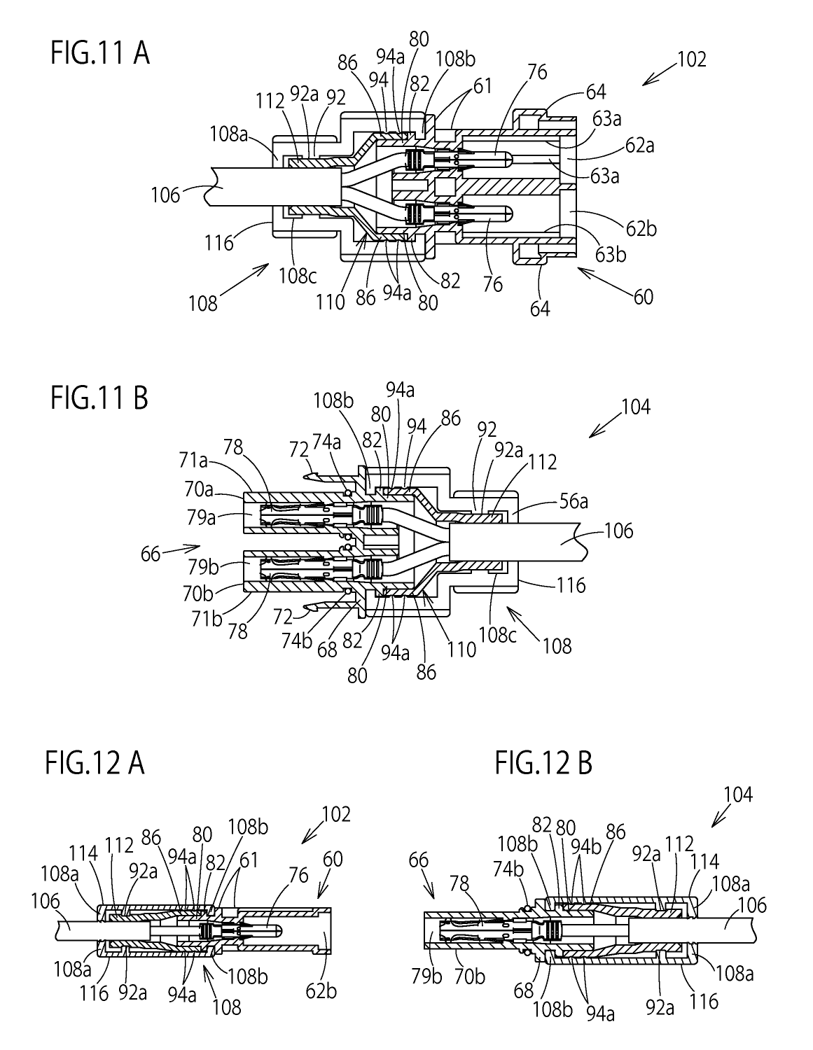

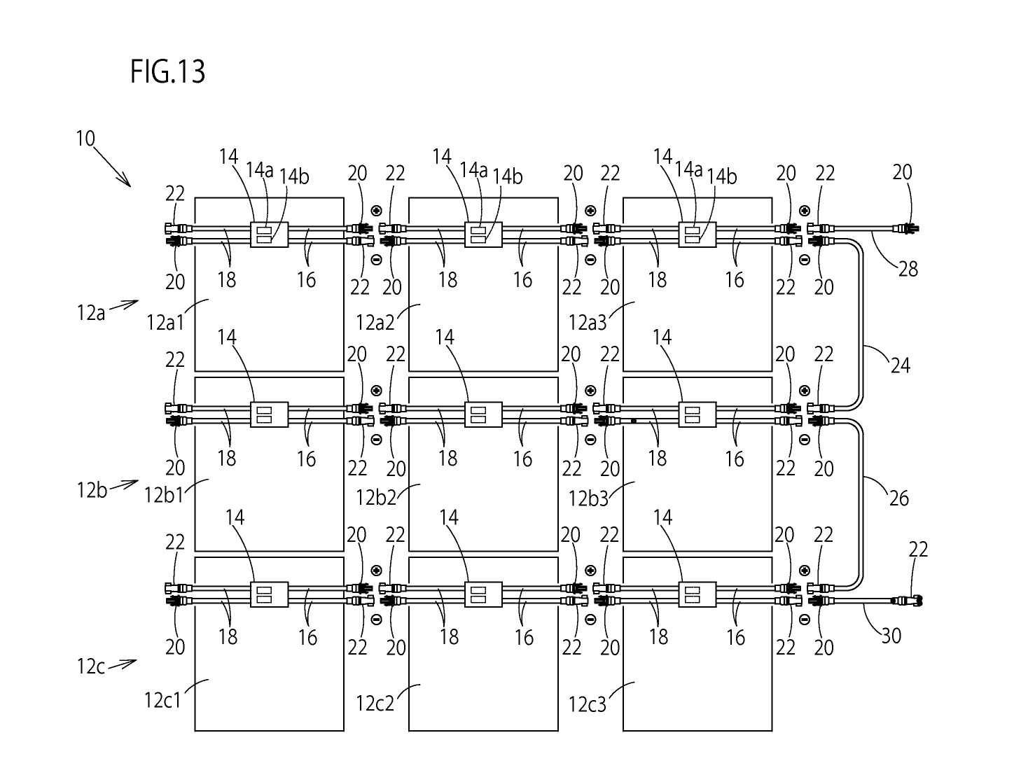

Next, a male side plug 102 and a female side plug 104, which constitute a second embodiment of the watertight connector of the present invention, will be explained referencing FIG. 11 and FIG. 12. Here, constituent members that are the same as those in the male side plug 42 and the female side plug 44 of the first embodiment are assigned the same symbols, and explanations thereof are therefore omitted. The male side plug 102 and the female side plug 104 have structures suited to a watertight connector used in the connection of a single dual core cable 106.

With regard to the male side plug 102 and the female side plug 104 shown in FIG. 11 and FIG. 12, the plug is mounted to the single dual core cable 106, which is split into two core wires that are drawn out, and two male side terminal fittings 76 are mounted to the end parts of the two core wires and housed inside the male side plug 102. Furthermore, here, instead of the insulation casing 56 and the sealing material member 84 that correspond to the two single core cables 58, an insulation casing 108, which is an insulating member, and a sealing material member 110, which is a watertight member, are used. Further, the plug housings 60, 66 are also used as is.

The sealing material member 110, which is fitted to the rear end protruding part 80 of the male side plug housing 60, comprises: the large diameter part 86, which has a comparatively large elliptical cylindrical shape, and a cylindrically shaped small diameter part 112, which is formed continuously with the large diameter part 86 and has a comparatively small outer diameter. Furthermore, the shape of the large diameter part 86 of the sealing material member 110 is the same as that of the large diameter part 86 of the sealing material member 84.

The insulation casing 108 comprises an upper cover 114 and a lower cover 116, which, when viewed from above, have substantially protruding external shapes; furthermore, one semicircular notch is provided to a rear wall 108a of each of the covers 114, 116, and these form a single substantially circular opening in the assembled state. In addition, an inner wall surface 108c, which is disposed slightly inward of the rear wall 108a of each of the covers 114, 116, is provided with a small diameter part supporting wall 92 and a large diameter part supporting walls 94 such that they connect laterally opposing sidewalls. Further, the small diameter part supporting wall 92 is provided with one support surface 92a, the upper end of which is recessed in a semicircle; in addition, the diameter of the support surface 92a is set slightly smaller than the outer diameter of the small diameter part 112 of the sealing material member 110 that covers the outer circumferential surface of the dual core cable 106. In addition, the shapes of the large diameter part supporting wall 94 and the support surfaces 94a of both the upper cover 114 and the lower cover 116 are the same as those of the upper cover 52 and the lower cover 54. Moreover, the shapes of front walls 108b, whose upper ends are provided with semi-elliptically shaped notches, of both the upper cover 114 and the lower cover 116 are the same as those of the front walls 56b of the upper cover 52 and the lower cover 54.

The method of assembling the male side plug 102 and the female side plug 104 is the same as that of the male side plug 42 and the female side plug 44 discussed above. Further, in the assembled state, the small diameter part 112 of the sealing material member 110 is pinched in a state of close contact between the support surfaces 92a, 92b and the outer circumferential surface of the dual core cable 106, thereby sealing the spaces on the outer and inner sides of the sealing material member 110. Similarly, the large diameter part 86 of the sealing material member 110 is pinched in a state of close contact between the support surfaces 94a and the outer circumferential surface of the rear end protruding part 80, thereby sealing the spaces on the outer side and the inner side of the sealing material member 110.

As explained above, with the exception of the insulation casing 108 and the sealing material 110 of the present embodiment, the same constituent members of the male side plug 42 and the female side plug 44 that correspond to the single core cables 58 of the first embodiment can be used as is in the male side plug 102 and the female side plug 104 that correspond to the dual core cables 106, which is very convenient from the standpoint of materials control.

Furthermore, the watertight connector of the present invention is not limited to the abovementioned embodiments. For example, the mating relationship between the male side plug housing and the female side plug housing is not limited to the present embodiment; in particular, a structure may be adopted wherein they are mated such that the male side plug housing covers the female side plug housing. The mating structure of the male side plug housing and the female side plug housing of the invention of the present application does not matter as long as the plug housings are capable of housing the male side and female side terminal fittings. In the abovementioned embodiments, the watertight structure that pinches the sealing material is a sealed structure wherein the single core or dual core cable, the insulation casing, and the male side or female side plug housing pinch the sealing material member at a plurality of locations. However, depending on the size of the cables used and on constraints in the structural design of both the insulation casing and the plug housings, a sealed structure wherein the sealing material member is pinched at least one location may be adopted, which makes it possible to secure a degree of watertightness above a certain level.

Accordingly, the invention is to be limited only by the scope of the claims and their equivalents.

1. A watertight connector, comprising:
a male side plug and a female side plug, each of which comprises:
a pair of terminal fittings, wherein a mating portion that mates with a counterpart side is provided to a tip of each terminal fitting, wherein each of the terminal fittings is mounted to an end part of an electrical line;
a plug housing,
an insulation member, which encloses at least a rear end part of the plug housing and the end parts of electrical lines; and
a watertight member, which prevents moisture from penetrating into the insulation member;
wherein
the watertight member comprises a tubular sealing material member that is mounted such that it spans outer circumferential surfaces of the electrical wiring lines and the plug housing;
a rear end part of the plug housing, which holds the pair of terminal fittings, is housed in an inner wall surface which is formed in a hollow of the insulation member and an openings in the insulation member exposes a front end part of the plug housing to the outside of the insulation member; and
the inner wall surface of the insulation member, the outer circumferential surfaces of the electrical wiring lines and the rear end part of the plug housing are brought into close contact with the sealing material member, thereby coupling the plug housing and the insulation member in a watertight state.

2. A watertight connector according to claim 1, wherein
the insulation member configured for mounting to either of the male side plug housing and the female side plug housing; and
each of the mating parts of the male side and female side plug housings are configured for mating with and connecting to only a terminal fitting of a corresponding polarity.

3. A watertight connector according to claim 1, wherein the insulation member comprises an insulation casing, which is provided with a support wall that has a tip edge that makes contact with an outer circumferential surface of the sealing material member at the inner wall surface in the vicinity of the opening, and outer circumferential surfaces of the support wall and the rear end part of the plug housing make close contact with the sealing material, thereby coupling the plug housing and the insulation casing in a watertight state.

4. A watertight connector according to claim 3, wherein an outer circumferential surface of the male side plug housing and an outer circumferential surface of the female side plug housing each pinch a corresponding sealing material member against the support wall, thereby coupling the corresponding plug housing and the corresponding insulation casing in the watertight state.

5. A watertight connector according to claim 1, wherein
the sealing material member is configured for mounting to both the terminal fittings and the plug housing on either of the male side or the female side.

6. A photovoltaic power generating apparatus that has a plurality of solar panels, each solar panel comprising photovoltaic cells, wherein output terminals that each comprise a pair of two poles for each of the solar panels are connected via a watertight connector and a cable, and the electric power generated by the plurality of solar panels is output collectively, wherein
a watertight connector that comprises a male side plug and a female side plug, each of which comprises:
pair of terminal fittings, wherein a mating portion that mates with a counterpart side is provided to a tip of the terminal fitting, wherein each of the terminal fittings is mounted to an end part of an electrical line;
a plug housing, for mounting the terminal fittings;
an insulation member, which encloses at least a rear end part of the plug housing and the end parts of the electrical lines; and
a watertight member, which prevents moisture from penetrating into the insulation member;
wherein
the watertight member comprises a tubular sealing material member that is mounted such that it spans the outer circumferential surfaces of the electrical wiring lines and the plug housing;
the rear end part of the plug housing, which holds the pair of terminal fittings, is housed in an inner wall surface_{;} which is formed in a hollow of the insulation member, and an opening in the insulation member externally exposes the insulation member, are formed in a front end part of the plug housing; and
the inner wall surface of the insulation member; the outer circumferential surfaces of the electrical wiring lines and the rear end part of the plug housing are brought into close contact with the sealing material member, thereby coupling the plug housing and the insulation member in a watertight state; and
in each of the solar panels, the male side plug and the cable are connected to one of the output terminals and the female side plug cables are connected to the other output terminal, whereby adjacent solar panels are connected to one another by the male side plug on one side and the female side plug on the other side; and
in each of the solar panels, output terminals of the same polarity are connected to one via the male side plug and the female side plug, which are mated to one another, and the solar panels are electrically connected in parallel.

7. A photovoltaic power generating apparatus that comprises a plurality of solar panel groups, each of which is formed by connecting a plurality of the solar panels in parallel, and is formed by connecting each of the solar panel groups with a harness, wherein
a male side or a female side plug is provided to a terminal of each of the solar panel groups;
the female side or male side plug, which mates with a corresponding male side or female side plug, is provided in the same number as the solar panel groups to the harness; and
the harness connects each of the solar panel groups in series.

8. A watertight connector according to claim 2, wherein the insulation member comprises an insulation casing, which is provided with a support wall that has a tip edge that makes contact with all outer circumferential surface of the sealing material member at the inner wall surface in the vicinity of the opening, and outer circumferential surfaces of the support wall and the rear end part of the plug housing make close contact with the sealing material, thereby coupling the plug housing and the insulation casing in a watertight state.

9. A watertight connector according to claim 8, wherein an outer circumferential surface of the male side plug housing and an outer circumferential surface of the female side plug housing each pinch a corresponding sealing material member against the support wall, thereby coupling the corresponding plug housing and the corresponding insulation casing in the watertight state.

10. A watertight connector according to claim 2, wherein the sealing material member is configured for mounting to both the terminal fittings and the plug housing on either of the male side or the female side.

11. A watertight connector according to claim 3, wherein the sealing material member is configured for mounting to both the terminal fittings and the plug housing on either of the male side or the female side.

12. A watertight connector according to claim 4, wherein the sealing material member is configured for mounting to both the terminal fittings and the plug housing on either of the male side or the female side.

13. A watertight connector according to claim 8, wherein the sealing material member is configured for mounting to both the terminal fittings and the plug housing on either of the male side or the female side.

14. A watertight connector according to claim 9, wherein the sealing material member is configured for mounting to both the terminal fittings and the plug housing on either of the male side or the female side.

15. A watertight connector, comprising:
at least one of a male side plug and a female side plug, each of which comprises:
a pair of terminal fittings, wherein a mating portion that mates with a counterpart side is provided to a tip of each terminal fitting, wherein each of the terminal fittings is mounted to an end part of an electrical line;
a plug housing for mounting the terminal fittings;
an insulation member, which encloses at least a rear end part of the plug housing and the end parts of electrical lines; and
a watertight member, which prevents moisture from penetrating into the insulation member;
wherein
the watertight member comprises a tubular sealing material member that is mounted such that it spans outer circumferential surfaces of the electrical wiring lines and the plug housing;
a rear end part of the plug housing, which holds the pair of terminal fittings, is housed in an inner wall surface which is formed in a hollow of the insulation member and an opening in the insulation member exposes a front end part of the plug housing to the outside of the insulation member; and
the inner wall surface of the insulation member, the outer circumferential surfaces of the electrical wiring lines and the rear end part of the plug housing are brought into close contact with the sealing material member, thereby coupling the plug housing and the insulation member in a watertight state.
